(19) United States
(12) Patent Application Publication
(10) Pub. No.: US 2024/0429249 A1
(43) Pub. Date: Dec. 26, 2024

(54) THIN-FILM TRANSISTOR DRIVING DEVICE AND MANUFACTURING METHOD THEREOF

(71) Applicant: SEOUL NATIONAL UNIVERSITY R&DB FOUNDATION, Seoul (KR)

(72) Inventors: Soo Yeon LEE, Seoul (KR); Jin Kyu LEE, Seoul (KR)

(73) Assignee: SEOUL NATIONAL UNIVERSITY R&DB FOUNDATION, Seoul (KR)

(21) Appl. No.: 18/693,428

(22) PCT Filed: Jun. 8, 2023
(86) PCT No.: PCT/KR2023/007876

§ 371 Date: Mar. 19, 2024

(30) Foreign Application Priority Data
Jun. 9, 2022 (KR) 10-2022-0069932
Jun. 8, 2023 (KR) 10-2023-0073437

(51) Int. Cl. H01L 27/12; H01L 29/417; H01L 29/49; H01L 29/66

(52) U.S. Cl. CPC H01L 27/1248; H01L 27/1225; H01L 29/41733; H01L 29/4908; H01L 29/66742

(57) ABSTRACT

The present invention relates to a driving device and a method for manufacturing same, the driving device comprising: a substrate; an insulating layer positioned on the substrate; a channel layer positioned on at least a portion of the insulating layer and including a metal oxide; and a source electrode and a drain electrode which are connected to the channel layer and positioned on the insulating layer to face each other on both sides of the channel layer, wherein the insulating layer comprises: a first insulating layer formed directly on the substrate; and a second insulating layer formed in the width direction at a certain height at the center of the upper surface of the first insulating layer, wherein the length of the second insulating layer is less than the length of the first insulating layer, stepped portions are formed on both sides of the second insulating layer, which respectively face the source electrode and the drain electrode, the stepped portions are spaced apart from the source electrode and the drain electrode in the longitudinal direction, and steps are formed in the channel layer due to the stepped portions.

### TECHNICAL FIELD

The present invention relates to a thin film transistor driving device and a manufacturing method thereof, and more specifically, relates to a thin film transistor driving device in which changes in device characteristics due to diffusion of n+ region from a source electrode and a drain electrode can be inhibited even in a short channel with a short channel length and a manufacturing method thereof.

### BACKGROUND ART

A driving device is one kind of semiconductor devices used for converting or amplifying electrical signals, and is used in various fields such as computers, communications, control, medicine, automobiles and home appliances and the like.

Among the semiconductor driving devices, a thin film transistor (TFT) is one of core devices of integrated circuits, and is a device driving a screen using a transistor formed of a thin film. The thin film transistor driving device is known as a technology that has begun to be used mainly in liquid crystal displays, and it is general to configure a liquid crystal panel with a backlight to display colors.

In addition, the thin film transistor driving device is used for OLED and LCD displays used in large/small devices. This device had advantages of low power consumption, providing high resolution and high contrast, and rapid response speed. Moreover, the TFT driving device has an advantage of providing a better viewing angle compared to other types of liquid crystal displays. Element technologies of such a TFT driving device have been continuously developed, and now it is widely used in not only most mobile devices but also high-frequency signal amplifiers, optical communication receivers and the like.

The structure of the thin film transistor is a basic semiconductor material in which the thin film transistor is generally positioned, and consists of a substrate mainly using a silicon wafer, a gate electrode used for controlling currents, a channel providing a path through which currents flow into the area between the gate and substrate, and source and drain electrodes which are electrodes positioned on both sides of the channel and are responsible for inflow and outflow of currents.

Silicon (Si) is most widely used as the semiconductor material of the thin film transistor. Silicon is divided into amorphous silicon and polycrystalline silicon depending on the crystal form, and amorphous silicon has a simple manufacturing process, but has low charge mobility, so has limitations in manufacturing a high-performance thin film transistor, and polycrystalline silicon has high charge mobility, but requires a step of crystallizing silicon, so there is a problem of high manufacturing costs and complicated processes.

In order to complement disadvantages of these amorphous silicon and polycrystalline silicon, a thin film transistor using an oxide semiconductor which has higher electron mobility and a higher on/off ratio than the amorphous silicon, and has a cheaper production cost and higher uniformity than the polycrystalline silicon is attracting attention.

Oxide semiconductors have higher electrical stability and low power consumption than general semiconductor devices, so their utilization is gradually increasing in various fields such as displays, solar cells, sensors and the like. In particular, the utilization is high in the display field, because the performance of displays can be significantly improved due to high electrical stability and low power consumption of oxide semiconductors. In addition, the oxide semiconductors are evaluated as their availability is high in development of devices in the new field such as flexible displays.

However, in case of the oxide semiconductor thin film transistor, there is a problem that device characteristics change, such as the threshold voltage (Vₜₕ) moving in the negative direction as the channel length decreases. In addition, this problem is known to cause a doping effect of the channel due to carrier diffusion from the n+ doped source/drain region, and further increasing the electron concentration of the device by these n+ region to cause changes in the threshold voltage.

The shorter the channel length, the greater the influence according to the diffusion in the n+ region, so in general, it is more of a problem in a short channel thin film transistor driving device with a channel length less than about 3 μm. In order to reduce the changes in the threshold voltage in this short channel thin film transistor, various studies are being conducted to control the n+ diffusion region in the channel, such as application of various layers, light irradiation, ion implantation, gas surface treatment and the like.

### PRIOR ART

### Patent Document

(Patent document 1) Korean Patent Publication No. 10-2022-0018759

### DISCLOSURE

### Technical Problem

An object of the present invention is to provide a thin film transistor driving device which can effectively control n+ diffusion region in a channel layer at low cost and a manufacturing method thereof.

An object of the present invention is not limited to the object mentioned above, and other objects not mentioned can be clearly understood from the following description by those skilled in the art.

### Technical Solution

In order to solve the afore-mentioned problems, the present invention provides a driving device, comprising a substrate; an insulating layer positioned on the substrate; a channel layer which is positioned on at least some areas of the insulating layer and comprises metal oxide; and a source electrode and a drain electrode which are connected to the channel layer, and are positioned on the insulating layer to face each other on both sides centered on the channel layer, and the insulating layer comprises a first insulating layer formed directly on the substrate; and a second insulating layer formed along the width direction at a certain height in the center of the upper surface of the first insulating layer, the length (L_{I2}) of the second insulating layer is smaller than the length (L_{I1}) of the first insulating layer, and a step part is formed on both sides of the second insulating layer facing the source electrode and the drain electrode, respectively, and the step part is spaced apart in the longitudinal direction for the source electrode and the drain electrode, and a step is formed in the channel layer by the step part.

According to one example, the height of the second insulating layer may be 50% or more of the height of the channel layer.

According to one example, the height of the second insulating layer may be less than 100% of the height of the channel layer.

According to one example, the n+ diffusion region may be formed on the channel layer between the step part and the source electrode, and between the step part and the drain electrode.

According to one example, the length (L_{c}) of the channel layer may be longer than the length (L_{I2}) of the second insulating layer.

According to one example, a gate insulating layer positioned on the channel layer; and a gate electrode positioned on the gate insulating layer may be further comprised.

According to one example, the length (L_{I2}) of the second insulating layer may be equal to or less than the length of the gate electrode.

According to one example, the metal oxide of the channel layer may comprise indium-gallium-zinc oxide (IGZO).

According to one example, the insulating layer may comprise at least one of silicon oxide (SiO₂), silicon nitrite (SiN_{y}) and alumina (Al₂O₃).

According to one example, the gate insulating layer may comprise silicon oxide or alumina (Al₂O₃).

According to one example, the driving device may be a short channel driving device in which the length (L_{c}) of the channel layer is less than 3 μm.

According to another example of the present invention, the present invention provides a manufacturing method of a driving device, comprising preparing a substrate; forming a first insulating layer on the substrate; forming a second insulating layer along the width direction at a certain height in the center of the upper surface of the first insulating layer; forming a channel layer comprising metal oxide to cover at least some of the first insulating layer and all of the second insulating layer; forming a gate insulating layer and a gate electrode on the channel layer with a length equal to or more than the length of the second insulating layer; and forming a source electrode and a drain electrode to face each other on both sides centered on the channel layer, and a step part is formed on both sides of the second insulating layer facing the source electrode and the drain electrode, respectively, and the step part is spaced apart in the longitudinal direction for the source electrode and the drain electrode, and a step is formed in the channel layer by the step part.

According to another example, the driving device may be a short channel driving device in which the length (L_{c}) of the channel layer is less than 3 μm.

According to another example, the metal oxide of the channel layer may comprise indium-gallium-zinc oxide (IGZO).

### Advantageous Effects

According to the configuration of the present invention described above, a thin film transistor driving device which is highly compatible with conventional processes and has a low unit cost, and can effectively control diffusion of the n+ region, compared to conventional various methods for controlling n+ diffusion region in a channel, and a manufacturing method thereof can be provided.

### BRIEF DESCRIPTION OF THE DRAWINGS

FIG. 1 is a drawing which briefly shows a cross-sectional side cut in the thickness direction of the driving device according to one example of the present invention.

FIG. 2 shows the manufacturing method of the driving device according to another example of the present invention step by step.

FIG. 3 is a graph showing the transfer curve measured for the driving device of the prior art and the driving device according to one example of the present invention by comparison.

FIG. 4 is a graph measuring the transfer curve of the driving device depending on the height of the second insulating layer.

FIG. 5 is a drawing which briefly shows a cross-sectional side cut in the thickness direction of the driving device according to the prior art.

### MODE FOR INVENTION

Examples of the present invention are illustrated for the purpose of describing the technical spirit of the present invention. The scope according to the present invention is not limited to examples or detailed description for these examples presented below.

All technical terms and scientific terms used in the present invention, unless otherwise defined, have meanings commonly understood by those skilled in the art to which the present invention pertains. All terms used in the present invention are selected for the purpose to more clearly describe the present invention, and are not selected to limit the scope according to the present invention.

Expressions such as “comprising”, “with”, “having” and the like used in the present invention, unless otherwise stated in the phrase or sentence comprising the corresponding expression, should be understood as open-ended terms containing possibility to include other examples.

In the present invention, when a part such as a layer, membrane, area, plate and the like is said to be “above” or “on” another part, this not only the case in that it is “directly on” another part, but also the case in that there is another part in between. On the contrary, that it is said to be “above” or “on” the standard part means being positioned above or below of the standard part, and does not necessarily mean being positioned “above” or “on” the direction opposite to gravity.

In the present invention, “plane image” refers to the object of the present invention viewed from above, and “cross-sectional image” means the cross section, in which the object of the present invention is vertically cut, viewed from the side.

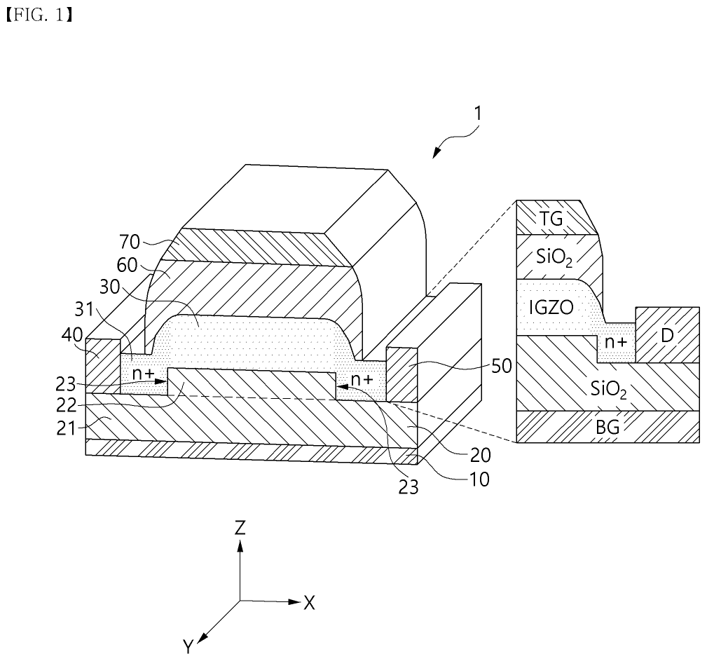

In the present invention, based on FIG. 1, x direction is defined as “longitudinal direction”, and y direction (that is, width direction of a source electrode or drain electrode) is defined as “width direction”, and z direction (that is, direction in which layers are stacked) is defined as “thickness direction”. In addition, based on the example shown in FIG. 1, the left side of the drawing is defined as left, and the right side of the drawing is defined as right.

Expressions of the singular form described in the present invention may include a meaning of the plural form unless otherwise mentioned, and this is applied to expressions of the singular form described in the claims in the same manner.

Hereinafter, with reference to the accompanied drawings, the examples of the present invention will be described. In this process, the thickness of the lines or size of the elements or the like illustrated in the drawings may be illustrated exaggeratedly for clarity and convenience of description. In addition, in the description of the following examples, describing the same or corresponding elements repeatedly may be omitted. However, even if the description for the elements is omitted, it is not intended to be that such elements are not included in any example.

In addition, the following examples do not limit the scope of the present invention, but are exemplary points of the elements presented in the claims of the present invention, and examples comprising elements which are included in the technical spirit of the entire description of the present invention and can be substituted with equivalents in the elements of the claims can be included in the scope of the present invention.

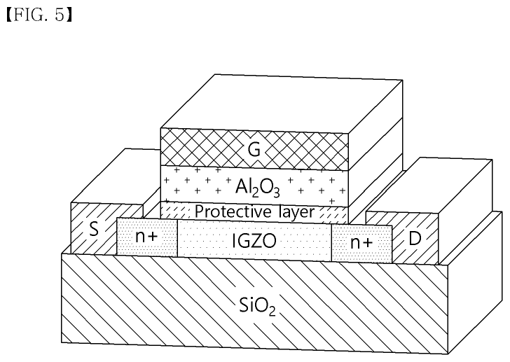

FIG. 5 briefly shows the driving device according to the prior art. The conventional driving device is generally composed to comprise an insulating layer (SiO₂) formed on a substrate (not shown), an IGZO channel layer formed on this insulating layer, a source electrode and a drain electrode, as shown in FIG. 5. In common, in this insulating layer, the upper surface is evenly formed, and thereby, the lower surface of the channel layer, source electrode and drain electrode is positioned on the substantially same plane.

When a doping effect of the channel is generated by carrier diffusion from the n+ doped source electrode and drain area, as shown in FIG. 5, n+ diffusion region is formed in the side area connected to the source electrode of the channel layer and the side area connected to the drain electrode. If the n+ diffusion region is formed too much, the effective channel length is reduced and the device electron concentration is increased, so a problem causing changes in device characteristics such as changes in the threshold voltage, and the like is generated. In addition, this problem is noticeably shown in the short channel driving device in which the channel length is less than approximately 3 μm.

To solve the problem of the changes in device characteristics due to the increase of the n+ diffusion region, many attempts and researches have been conducted in various aspects, but as complex processes are added, the unit cost increase is caused and therefore it is difficult to apply to actual mass production in many cases, and in addition, n+ region diffusion cannot be precisely controlled in many cases. Accordingly, the present inventors have studied the method for controlling diffusion in terms of precisely controlling n+ region diffusion with low costs through modification of the structure of the device in depth, resulting in completing the present invention.

Hereinafter, with reference to FIG. 1, the driving device (1) according to one example of the present invention will be described in detail.

FIG. 1 is a perspective view briefly showing the driving device (1) according to one example of the present invention. As shown in FIG. 1, the driving device (1) according to one example of the present invention, may comprise a substrate (10); an insulating layer (20) positioned on the substrate (10); a channel layer (30) which is positioned on at least some areas of the insulating layer (20) and comprises metal oxide; and a source electrode (40) and a drain electrode (50) positioned on the insulating layer (20) to face each other on both sides centered on the channel layer (30).

Referring to FIG. 1, at first, the substrate (10) is provided, and the insulating layer (20) is formed on this substrate (10). The thickness of the insulating layer (20) does not affect the desired effect of the present invention, so its thickness may not be particularly limited. As one non-restrictive example, the thickness of the insulating layer (20) may be formed as 100˜300 nm, which is the thickness commonly used to control the threshold voltage. The insulating layer (20) comprises an insulating material, and this insulating material may comprise at least one of silicon oxide (SiO₂), silicon nitrite (SiN_{y}) and alumina (Al₂O₃). The insulating layer (20) is generally formed through a separate film forming process mostly before forming the channel layer (30).

The insulating layer (20) comprised in the driving device (1) according to one example of the present invention, may comprise a first insulating layer (21) formed directly on the substrate (10), and a second insulating layer (22) formed along the width direction at a certain height in the center of the upper surface of this first insulating layer (21). In other words, as shown in FIG. 1, the first insulating layer (21) may be formed with a certain thickness directly on the substrate (10), preferably, on the substantially entire areas at which the device is to be formed in the upper surface of the substrate (10), and the second insulating layer (22) may be formed long in the width direction on at least some areas of the first insulating layer (21) along the center of the upper surface. Preferably, the first insulating layer (21) may be formed with a thickness, as a relatively thicker layer, and the second insulating layer (22) may be formed in a rectangular parallelepiped shape with a relatively thinner thickness.

In addition, as shown in FIG. 1, the length (L_{I2}) of the second insulating layer (22) may be formed smaller than the length (L_{I1}) of the first insulating layer (21), and a step part (23) extending to the width direction is formed on each of both sides of the second insulating layer facing the source electrode (40) and the drain electrode (50). Therefore, the cross section in which the insulating layer in which both the first insulating layer (21) and the second insulating layer (22) are formed is cut in the longitudinal direction may have a [symbol] shape. The step part (23) is preferably formed vertically from the upper surface of the first insulating layer (21), but it is not necessarily limited thereto, and it is irrelevant to be formed at a certain inclination.

As shown in FIG. 1, each of the step parts (23) on both sides is spaced apart in the longitudinal direction for the source electrode (40) and drain electrode (50). Through controlling the length (L_{I2}) of the second insulating layer (22), the interval between the step part (23) and source electrode (40) and between the step part (23) and drain electrode (50) can be controlled.

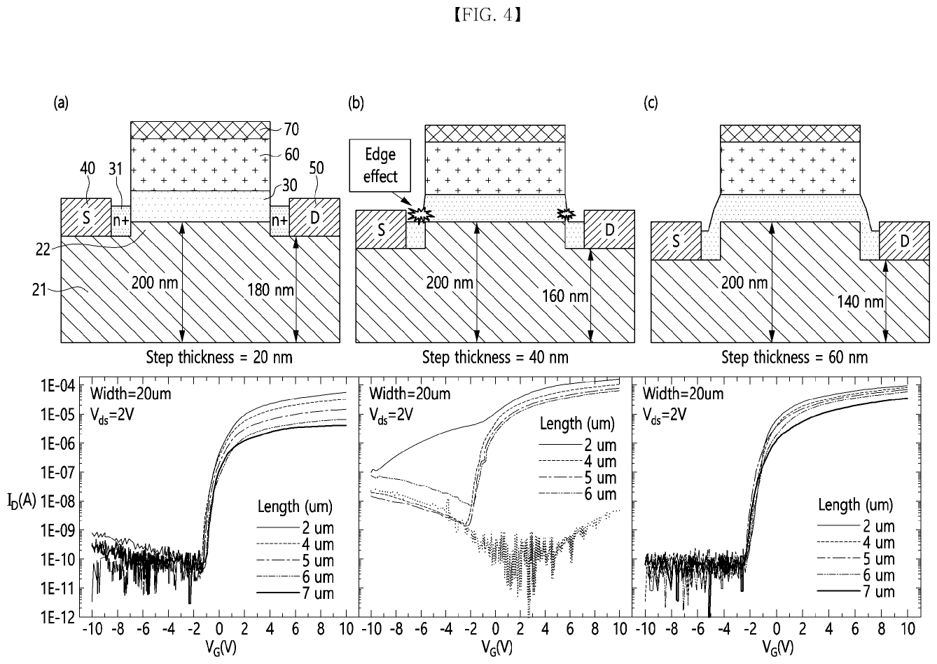

The height of the second insulating layer (22) is preferably 50% or more of the height of the channel layer (30), and it is preferably 50% or more to less than 100%. When the height of the second insulating layer (22) is at least 50% or more of the height of the channel layer (30), an effect of inhibiting diffusion of the n+ region can be obtained (See (a) of FIG. 4). However, when the height of the second insulating layer (22) becomes excessively thicker than the thickness of the channel layer (30), the effect intended in the present invention can be equally obtained, but there is a risk of disconnection between the n+ region and channel layer (30), and in addition, there is a problem that the channel thickness becomes thin near the step between the n+ region and effective channel, and thus an electric field becomes stronger or resistance becomes greater, and therefore, changes in the device characteristics are caused, and therefore, the above ratio can be limited to less than 100%.

The channel layer (30) is formed on at least some areas of the insulating layer (20). It is preferable that the length (L_{c}) of the channel layer (30) is formed longer than the length (L_{I2}) of the second insulating layer (22). This channel layer (30) may comprise metal oxide, and preferably, this metal oxide may comprise indium-gallium-zinc oxide (IGZO). The indium-gallium-zinc oxide is a material recently spotlighted as a promising material in the semiconductor industry, and has transparent and flexible characteristics, and in addition, has high electrical conductivity and charge mobility, and thus, when the channel layer (30) is formed with indium-gallium-zinc oxide, the responsibility of the device is improved, and therefore, it becomes possible to implement a high-resolution display.

When the channel layer (30) is formed with a longer length (L_{c}) of the channel layer (30) than the length (L_{I2}) of the second insulating layer (22) on the insulating layer (20) having the aforementioned shape, the channel layer (30) is naturally formed not only on the second insulating layer (22) but also in the space between the step part (23) and the source electrode (40) and between the step part (23) and drain electrode (50) in the upper surface of the first insulating layer (21). In addition, as shown in FIG. 1, in the channel layer (30) on the second insulating layer (22) and the channel layer (30) on the first insulating layer are formed at each different heights by the step part (23) by the second insulating layer (22), and thereby, a step is formed.

Diffusion of the n+ region can be effectively controlled by the height change (that is, step) in the middle of this channel layer (30). Specifically, also in the driving device (1) according to one example of the present invention, as same as the prior art, carrier diffusion occurs from the source electrode (40) and drain electrode (50). However, unlike the prior art, in the middle of the channel layer (30) of the driving device according to one example of the present invention, a step by the step part (23) of the second insulating layer (22) is formed, and this step of the channel layer (30) interrupts diffusion of the n+ region. Through this, the n+ diffusion region (31) is formed only in the channel layer (30) between the step part (23) and source electrode (40) and between the step part (23) and drain electrode (50), and thereby, diffusion of the n+ region can be effectively controlled. In addition, a part of which position in the thickness direction is elevated by the step, that is, the channel layer (30) on the second insulating layer (22) may be always secured as an effective channel. Therefore, even if the channel length changes, the device characteristics can be maintained constant, and even if it is a short channel with a short channel length of less than 3 μm, the effective channel is always secured, so the device characteristics can be maintained constant.

On the insulating layer (20), in addition to the channel layer (30), the source electrode (40) and drain electrode (50) are positioned. The source electrode (40) and drain electrode (50) are electrodes responsible for the input and output of the transistor, and the source electrode (40) plays a role of supplying voltage or current input to the transistor, and the drain electrode (50) plays a role of collecting output signals from the transistor. These source electrode (40) and drain electrode (50) are connected to the channel layer (30), and are positioned to face each other on both sides centered on the channel layer (30). In other words, when described with reference to FIG. 1, the source electrode (40) and drain electrode (50) are formed, respectively, in contact with edges on both sides in the longitudinal direction of the channel layer (30). The source electrode (40) and drain electrode (50) may be made of metal or a conductor, and the specific material is not particularly limited, but it is preferable to be formed with molybdenum, chrome, nickel, titanium, copper, aluminum or an alloy thereof.

The gate insulating layer (60) and gate electrode (70) may be formed on the channel layer (30). The gate insulating layer (60) performs a role of electrically insulating the gate electrode (70) and channel layer (30). The thickness of the gate insulating layer (60) does not specially affect the effect desired by the present invention, so its thickness is not particularly limited, and as one non-restrictive example, it may be formed as 50˜200 nm, which is a commonly used thickness. The gate insulating film comprises an insulating material, and this insulating material may comprise silicon oxide (SiO₂) or alumina (Al₂O₃).

The gate electrode (70) is an element which controls operation of the transistor by applying electronic signals, and when voltage more than the threshold voltage (Vₜₕ) is applied to the gate electrode (70), the channel layer (30) is activated, and thereby, current flows from the source electrode (40) to the drain electrode (50). The length (L_{I2}) of the second insulating layer (22) may be equal to or less than the length of the gate electrode (70). The gate electrode may be made of metal or a conductor, and the specific material is not particularly limited, but it is preferable to be formed with at least one metal or alloy selected from the group consisting of aluminum, silver, copper, molybdenum, chrome, tantalum, titanium or alloys thereof. In addition, the length of the gate electrode (70) is not particularly limited, and preferably, it may be formed with the same length as the length of the second insulating layer (22).

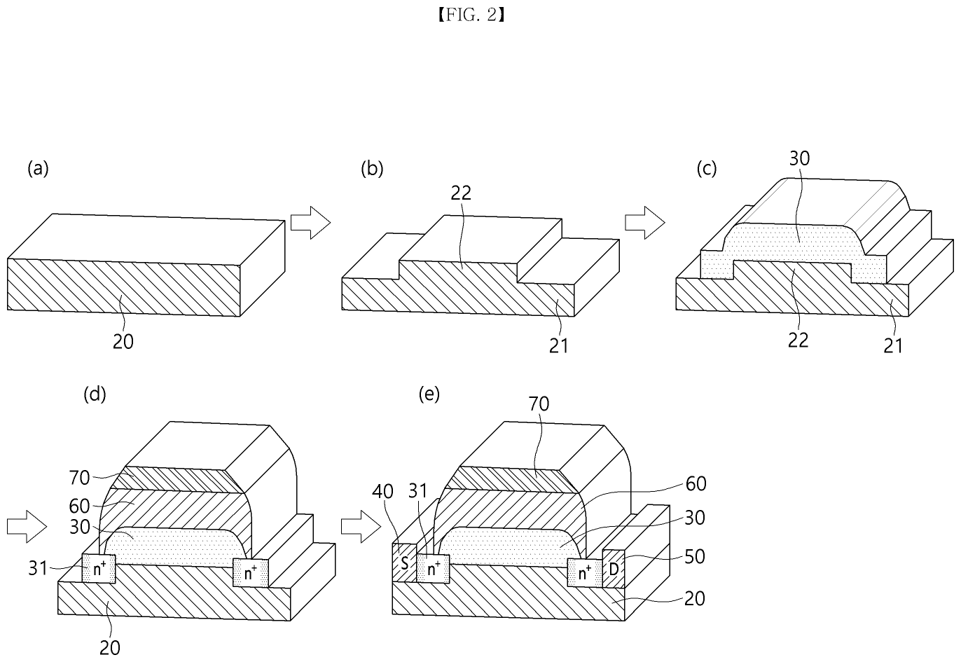

Next, for the manufacturing method of the driving device (1) according to another example of the present invention, it will be described with reference to FIG. 2. However, the manufacturing method described in the following is just any one example of various methods for manufacturing the driving device (1) according to one example of the present invention.

At first, the substrate (10) is prepared and the first insulating layer (21) is formed on the substrate (10). Then, the first insulating layer (21) may be formed on the substantially entire region in which the device is formed in the upper surface of the substrate (10) with a certain thickness. When an oxide film capable of playing the same role as the insulating layer (20) is already formed on the substrate (10), a step of forming the first insulating layer (21) may be omitted.

By film forming the second insulating layer (22) long in the width direction on at least some areas and center of the upper surface of the first insulating layer (21), a step part structure comprising the step part (23) is formed on both sides of the second insulating layer. The thickness of the second insulating layer (22) is formed by 50% or more of the thickness of the channel layer (30) to be formed later.

After that, the channel layer (30) comprising metal oxide, preferably, indium-gallium-zinc oxide (IGZO) on the first insulating layer (21) and the second insulating layer (22) is formed. Then, the length (L_{c}) of the channel layer (30) is formed longer than the length (L_{I2}) of the second insulating layer (22). The method for forming the channel layer (30) is not particularly limited, and a known technology such as solution processing, atomic layer deposition (ALD), sputter deposition (DC or RF), and the like may be used.

When the channel layer (30) is formed on the first insulating layer (21) and the second insulating layer (22) forming the step part structure, as shown in FIG. 1, the position in the thickness direction changes in the part corresponding to the step part (23) also in the channel layer, a step is formed.

Then, the gate insulating film and gate electrode (70) are formed on the channel layer (30), and the source electrode (40) and drain electrode (50) are formed to face each other centered in the channel layer (30) and to be contact with the channel layer (30), the driving device (1) according to one example of the present invention can be manufactured.

### Examples

Hereinafter, the effects of the driving device according to one example of the present invention will be described through experimental results.

### Method for Measuring Threshold Voltage (Vₜₕ)

In the experiment of the present invention, the device was measured through a probe station and a semiconductor analyzer (Keithley 4200-SCS), and as the device measurement condition, it was progressed at V_{DS}=2 V, which is the linear section. The threshold voltage was extracted through constant current method, and this method extracts the threshold voltage at a designated current value. The designated current value used in the present experiment is I_{DS}=1 nA.

### * Experiment 1

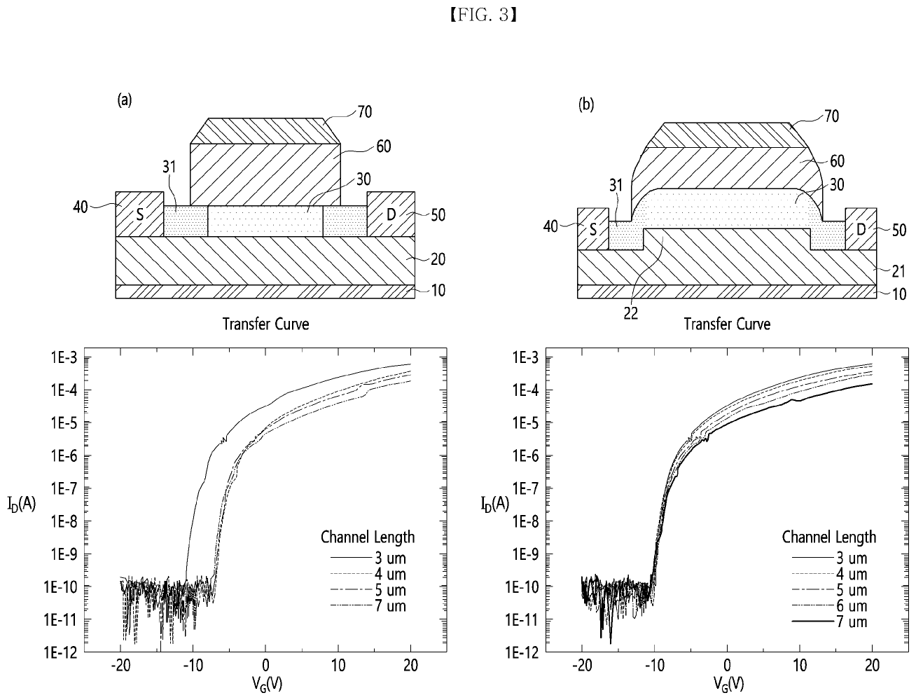

FIG. 3 is a graph showing the transfer curve measured for the driving device of the prior art and the driving device according to one example of the present invention by comparison.

The present inventors prepared a driving device of the prior art having the structure shown in (a) of FIG. 3 as a comparative example, and a driving device having the structure shown in (b) of FIG. 3 as an invention example, and formed the channel length (Lc) each differently per each invention example and comparative example, and after the experiment, they were shown in FIG. 3.

After that, the present inventors additionally designed the following experiments and obtained data to more specifically investigate the influence depending on the size of the step (height of the second insulating layer) as well as the length of the channel.

### * Experiment 2

FIG. 4 is a graph measuring the transfer curve of the driving device depending on the height of the second insulating layer.

The present inventors conducted an additional experiment to investigate the influence depending on the height of the second insulating layer for the driving device according to one example of the present invention.

At first, according to the manufacturing method described above, a plurality of driving devices having the structure as FIG. 1 were prepared, and for each driving device, it was manufactured to have the height and channel length (L) of the second insulating layer as the following Table 2. Then, it was formed identically for all the driving devices, as the combined height of the first and second insulating layers was 200 nm, and the height of the channel layer was 40 nm.

As same as Experiment 1, for each example, under the same conditions, the threshold voltage (Vth) of the driving device was measured, and the results were shown in FIG. 4.

### * Experiment 3

The present inventors conducted the third experiment for investigating the influence depending on the length of the channel and the height of the second insulating layer for the driving device according to one example of the present invention together. At first, according to the manufacturing method described above, a driving device in which the second insulating layer was not formed (Comparative example 1) was prepared, and in addition, 3 kinds of driving devices which had the same structure as FIG. 1 and had the height of the second insulating layer of 10 nm, 20 nm and 60 nm, respectively, were prepared (Comparative example 2, Invention example 1, Invention example 2, respectively). In addition, for each kind of driving device, driving devices having the channel length of 2 μm, 3 μm, 4 μm, 5 μm and 6 μm were manufactured, respectively. At this time, it was formed identically for all the driving devices, as the combined height of the first and second insulating layers was 200 nm, and the height of the channel layer was 40 nm.

For each of a total of 20 driving devices, under the same conditions, the threshold voltage (Vₜₕ) was measured, and the results were shown in Table 1.

TABLE 1

| | | Second | | | | | | | | | | |
|---|---|---|---|---|---|---|---|---|---|---|---|---|
| | | insulating | | | | | | | | | | |
| | Second | layer height | | | | | | | | | | |
| | insulating | ratio to | | | | | | | | | | |
| | layer | channel | | | | | | | | | | |
| | height | layer height | Channel length (μm) | | | | | | | | | |
| Classification | (nm) | (%) | 2 | | 3 | | 4 | | 5 | | 6 | |
| Comparative | 0 | 0 | −2.625 | V | −1.1 | V | −1.05 | V | −0.71 | V | −0.82 | V |
| example 1 | | | | | | | | | | | | |
| Comparative | 10 | 25 | −3.4 | V | −1.5 | V | −1.4 | V | −1.4 | V | −1.3 | V |
| example 2 | | | | | | | | | | | | |
| Invention | 20 | 50 | −0.825 | V | −0.9 | V | −0.71 | V | −0.6 | V | −0.48 | V |
| example 1 | | | | | | | | | | | | |
| Invention | 60 | 150 | −1.7 | V | −1.7 | V | −1.7 | V | −1.7 | V | −1.8 | V |
| example 2 | | | | | | | | | | | | |

As the experimental result, as could be confirmed from the results of Invention example 1 and Invention example 2, it could be confirmed that if the thickness of the second insulating layer was 50% or more of the thickness of the channel layer, and the channel length was reduced to less than 3 μm, diffusion of the n+ region was effectively inhibited. On the other hand, looking at the results of Comparative example 1 and Comparative example 2, the results that the threshold voltage moved to the negative direction in the short channel with the channel length of 2 μm and thereby, the device characteristics changed were shown.

The above description is illustratively describing the technical spirit of the present invention only, and those skilled in the art to which the present invention belongs can make various modification and variation in a range without departing from essential characteristics of the present invention. Therefore, the examples disclosed in the present invention are not intended to limit the technical spirit of the present invention, but are intended to describe it, and the scope of the technical spirit of the present invention is not limited. The scope of the present invention should be construed according to the claims below, and all the technical spirits within the equivalent range thereto should be construed as being included in the scope of the present invention.

### Description of the Symbols

1: Driving device

10: Substrate

20: Insulating layer

21: First insulating layer

22: Second insulating layer

23: Step

30: Channel layer

31: n+ diffusion region

40: Source electrode

50: Drain electrode

60: Gate insulating layer

70: Gate electrode

1. A driving device,
comprising
a substrate;
an insulating layer positioned on the substrate;
a channel layer which is positioned on at least some areas of the insulating layer and comprises metal oxide; and
a source electrode and a drain electrode which are connected to the channel layer, and are positioned on the insulating layer to face each other on both sides centered on the channel layer;
wherein the insulating layer,
comprising
a first insulating layer formed directly on the substrate; and
a second insulating layer formed along the width direction at a certain height in the center of the upper surface of the first insulating layer, and
the length (L_{I2}) of the second insulating layer is smaller than the length (L_{I1}) of the first insulating layer, and
a step part is formed on both sides of the second insulating layer facing the source electrode and the drain electrode, respectively, and
the step part is spaced apart in the longitudinal direction for the source electrode and the drain electrode, and a step is formed in the channel layer by the step part.

2. The driving device according to claim 1,
wherein the height of the second insulating layer is 50% or more of the height of the channel layer.

3. The driving device according to claim 2,
wherein the height of the second insulating layer is less than 100% of the height of the channel layer.

4. The driving device according to claim 1,
wherein the n+ diffusion region is formed on the channel layer between the step part and the source electrode, and between the step part and the drain electrode.

5. The driving device according to claim 1,
wherein the length (L_{c}) of the channel layer is longer than the length (L_{I2}) of the second insulating layer.

6. The driving device according to claim 1,
further comprising
a gate insulating layer positioned on the channel layer; and
a gate electrode positioned on the gate insulating layer.

7. The driving device according to claim 6,
wherein the length (L_{I2}) of the second insulating layer is equal to or less than the length of the gate electrode.

8. The driving device according to claim 1,
wherein the metal oxide of the channel layer comprises indium-gallium-zinc oxide (IGZO).

9. The driving device according to claim 1,
wherein the insulating layer comprises at least one of silicon oxide (SiO₂), silicon nitrite (SiN_{y}) and alumina (Al₂O₃).

10. The driving device according to claim 6,
wherein the gate insulating layer comprises silicon oxide or alumina (Al₂O₃).

11. The driving device according to claim 1,
wherein the driving device is a short channel driving device in which the length (L_{c}) of the channel layer is less than 3 μm.

12. A manufacturing method of the driving device according to claim 1,
comprising
preparing a substrate;
forming a first insulating layer on the substrate;
forming a second insulating layer along the width direction at a certain height in the center of the upper surface of the first insulating layer;
forming a channel layer comprising metal oxide to cover at least some of the first insulating layer and all of the second insulating layer;
forming a gate insulating layer and a gate electrode on the channel layer with a length equal to or more than the length of the second insulating layer; and
forming a source electrode and a drain electrode to face each other on both sides centered on the channel layer,
wherein a step part is formed on both sides of the second insulating layer facing the source electrode and the drain electrode, respectively, and
the step part is spaced apart in the longitudinal direction for the source electrode and the drain electrode, and a step is formed in the channel layer by the step part.

13. The manufacturing method of the driving device according to claim 12,
wherein the driving device is a short channel driving device in which the length (L_{c}) of the channel layer is less than 3 μm.

14. The manufacturing method of the driving device according to claim 12,
wherein the metal oxide of the channel layer comprises indium-gallium-zinc oxide (IGZO).
